(19) United States
(12) Patent Application Publication
(10) Pub. No.: US 2026/0047452 A1
(43) Pub. Date: Feb. 12, 2026

(54) MOLDED POWER SEMICONDUCTOR PACKAGE FOR ENHANCED THERMAL OPERATION

(71) Applicant: Infineon Technologies Austria AG, Villach (AT)

(72) Inventors: Richard Knipper, Regensburg (DE); Wolfgang Seebach, Sauerlach (DE)

(21) Appl. No.: 19/297,206

(22) Filed: Aug. 12, 2025

(30) Foreign Application Priority Data
Aug. 12, 2024 (DE) 102024207655.4

(51) Int. Cl. H01L 23/495; H01L 23/00; H01L 23/31; H01L 23/36

(52) U.S. Cl. CPC H01L 23/49562; H01L 23/3107; H01L 23/36; H01L 23/49568; H01L 23/49575; H01L 24/48; H01L 2224/48245

(57) ABSTRACT

A semiconductor device includes a die carrier, a semiconductor die, a first set of external connectors, and a second set of external connectors. The semiconductor die includes at least a first load electrode and a second load electrode, and is mounted onto the die carrier with the first load electrode being electrically connected to the die carrier. The first set of external connectors is electrically and thermally connected to the die carrier. The second set of external connectors is spaced apart from the die carrier and electrically connected to the second load electrode. An overall wire size of the second set of external connectors is greater than an overall wire size of the first set of external connectors.

### TECHNICAL FIELD

The present disclosure relates to a semiconductor device comprising a die carrier, a first semiconductor die, comprising at least a first load electrode and a second load electrode, wherein the first semiconductor die is mounted onto the die carrier with the first load electrode being electrically connected to the die carrier, a first set of external connectors being electrically and thermally connected to the die carrier, and a second set of external connectors being spaced apart from the die carrier and electrically connected to the second load electrode.

### BACKGROUND

Current rating in TO-packages is limited by chip technology or drain pad area. When expanding current rating beyond a certain point (typically ˜150A in TO247), wider leads are required.

For solar applications, typically high lead /in length is required. In the following description the terms “pin”, “lead” and “connector” may be used as synonyms.

When exceeding the ampacity limit, ohmic heating of pins will cause a new overtemperature condition, that is, a temperature of the pins exceeds an allowed temperature. Moreover, the temperature of the pins may exceed an allowed temperature of the board material, for example of FR4, at a board connection point. This effect is most pronounced at the source leads, as no direct cooling connection to a possible heatsink exists. Commonly, source posts inside a package cool via leads into the board, whereas drain pins cool via the heatsink, that is, by way of the drain-pad connection.

Hence there is a general need to enhance cooling of the source connection.

### SUMMARY

According to a first aspect of the disclosure, a semiconductor device of the aforementioned kind is provided, wherein an overall wire size of the second set of external connectors is greater than an overall wire size of the first set of external connectors.

To facilitate a certain ampacity of each of the conductive elements of a load current path of the semiconductor device, a certain minimum wire size, that is a minimum conductive cross-section, is necessary throughout the load current path. However, all elements in the load current path heat up due to their own ohmic resistance when the semiconductor device is switched on. Hence, thermal energy which needs to be dissipated to the ambience is produced throughout the load current path. However, there are significant differences in thermal conductivity along the load current path. Particularly, the thermal conductivity at the source side is usually reduced in comparisons to the thermal conductivity at a drain side. This is because isolation properties at the source side differ from isolation properties at the drain side. As a result, effective temperatures at the source side, that is at the external source lead, are higher than at the drain side, that is at the external drain lead.

By designing an asymmetric lead count at equal lead size, additional source leads may be introduced which may be connected to isolated heatsinks, as electrical contact is not needed. Consequently, a wire size at the source connectors is larger than a wire size at the drain connectors. Particularly, a wire size of each connector of the first set of external connectors equals wire size of each connector of the second set of external connectors. However, the overall wire size, that is the overall conductive cross-section of the second set of external connectors is larger than the overall conductive cross-section of the first set of external connectors. This may allow for a better thermal management of the source post and allow for overall higher ampacity in discrete packages.

An asymmetric lead-ratio, that is, a non-equal lead-count of source and drain leads, allows a thermal split. For example, two pins input (drain) and three pins output (source) allow to contact one pin separately without reducing the ampacity of the load current path.

The additional pin may, for example, be used to contact an isolated heatsink on a Printed Circuit Board (PCB). Thereby the flux of thermal energy is split up, that is, distributed among the number of source pins. For example, four pins versus two pins would reduce thermal load by 50% and 3 pins versus two pins to 33%.

In an embodiment the semiconductor device comprises an encapsulant, encapsulating at least part of the first semiconductor die and at least proximal ends of each of the external connectors such that distal ends of both the external connectors of the first set of external connectors and the second set of external connectors protrude out of the encapsulant.

As the proximal ends of both the second set of external connectors and the first set of external connectors are buried in the encapsulant, heat generated by ohmic resistance inside the proximal portions of each of the sets of external connectors cannot be effectively lead away since the encapsulant acts as an isolator. Therefore, the heat generated at the proximal portions of the external connectors needs to be led outside of the encapsulant towards the distal ends of the external connectors by the external connectors themselves. Especially at the second set of external connectors, which may be a source connection, no direct connection to a die pad, which may act as a heat spreader, is available. Moreover, the external source connectors are heated up by possible internal connectors transporting heat from the source electrode to the source connectors. That is, regarding the section of the load current path from the source electrode of the semiconductor die towards the distal ends of the external source connectors, there is no further cooling possibility except for the external connectors themselves. By providing an asymmetrical wire size along the load current path, that is an increased wire size at the external source connectors, heat transfer from an inside of the encapsulant to an outside of the encapsulant is enhanced.

As a result of the above, a molded power semiconductor package with asymmetric pin/lead layout for thermally enhanced operation is provided.

In an embodiment, the die carrier is a leadframe, the leadframe comprising a first portion forming a die pad. The die carrier may be a leadframe consisting of a single sheet of ground metal. However, the die carrier may also be a ceramic or an AMB or a DCB or an Isolated Metal Substrate (IMS) or any other interposer. In addition, any isolation technique, like for example FullPak, Advanced Isolation or a Thermal Interface Material (TIM) sheet may be applied on the opposite side of the chip carrier. The die carrier may also be in contact or attached to a thermal interface material (TIM).

In an embodiment, the second set of external connectors comprises at least one additional connector with respect to the first set of external connectors.

Especially, the at least one additional connector is a thermal connector for facilitating heat transfer from an inside of the encapsulant to the ambient environment outside the semiconductor device. By providing an additional connector an asymmetrical pin count is provided. The pins being at equal size, an additional pin enlarges the wire size at the source connectors in comparison to the wire size at the drain connectors.

In an embodiment the semiconductor device comprises a lead post attached to the second set of external connectors, the lead post forming an integral part with the second set of external connectors. The second set of external connectors may be attached to a lead post, the lead post combining all of the connectors into one single, integral part. Thereby, the lead post may act as a heat spreader.

In an embodiment, the first set of external connectors is an integral part with the first portion of the leadframe. The drain leads may be formed by grounding together with the first portion of the leadframe and may hence be in integral thermal and electrical connection with the die pad. Consequently. The drain pins cool by way of the drain-pad connection. Particularly, the drain leads may cool via a heatsink that may be coupled to the leadframe. The first set of external connectors may have a downset towards the die carrier such that the drain leads are in-line and at equal height as the source leads.

In an embodiment the semiconductor device is a Single-In-Line-Package (SIP), wherein the first set of external connectors is laterally spaced apart from the second set of external connectors by a distance, which is larger than both a distance between external connectors of the first set of external connectors and a distance between external connectors of the second set of external connectors.

At a Single-In-Line Package, all external connectors are provided in a row at a common side, that is a common portion of a circumferential surface of the package. That is, all of the leads protrude out of the mold body in substantially the same direction and substantially parallel at the same surface of the mold body. In this embodiment, the source and the drain leads need to be spaced away from each other to maintain a clearance distance according to the voltage difference. Particularly, the drain leads may be arranged at a first side and the source and possible control leads may be arranged at a second, opposite side of the common portion of the circumferential surface. The drain leads and the group of source leads and possible control leads are spaced apart from one another forming an asymmetric in-line pin layout at the mold body.

A pocket may be arranged in the circumferential surface of the encapsulant between the first and second sets of external connectors to enhance a required creepage distance along the surface of the mold body between the drain and source connectors.

In an embodiment an outermost surface of the die carrier is exposed from the encapsulant. An exposed portion of the die carrier may be formed, for facilitating thermal connection to further devices. The exposed portion of the die carrier may also be referred to as exposed die pad.

Especially, the outermost surface of the die carrier may be configured to be attached to a heatsink. A thermal interface material may be arranged at the exposed outermost surface of the die carrier, to connect the semiconductor device to the heatsink.

In an embodiment a lateral dimension of each connector of the first set of external connectors equals a lateral extension of each connector of the second set of external connectors. That is, the connectors may be of an equal size. The connectors may also have the same conductive cross-section, that is, wire size. With an equal size of the connectors, attachment to second level devices, e.g. printed circuit boards, is facilitated, as only one size of second level connector, e.g. through hole on a PCB, is necessary. This reduces manufacturing effort at the customer side.

In an embodiment, the at least one additional connector is configured to be attached to a heatsink, for example to a copper plated insulated area at a Printed Circuit Board (PCB). Because the additional pin is not necessary for electrical purposes, that is, is not necessary for carrying the drain source current, the additional pin may be used as a term of pin. This means, that the additional pin is for thermal purposes only and can hence be used to connect to a heatsink, to cool the source connection.

In an embodiment the die carrier comprises a second portion, forming a tie-bar, wherein the second portion is arranged at an opposite side with respect to the external connectors. The tie-bar is arranged at an opposite side of the lead frame as side where the pins are attached. By the tie-bar, during the manufacturing process, an array of lead frames is kept in place. Especially, the tie-bar is a connection between the leadframes during the manufacturing process to provide mechanical stabilisation. A rotation of the leadframe(s) and therefore misalignment between the leadframe and the semiconductor die during the manufacturing process is prevented.

In an embodiment, the semiconductor device comprises a second semiconductor die attached to the die carrier, wherein the second semiconductor die is electrically and thermally connected to the lead post by an internal electrical connector, wherein the internal electrical connector is formed for example by one of wire bonding, wedge bonding, nail head bonding, or a clip. Especially, materials like Al, Cu or Ag may be used for the internal electrical connectors. The second semiconductor die may be a diode or a second transistor. Combinations of the transistor die and the diet or several transistors are possible. For example, the first semiconductor die and the second semiconductor die may also form half-bridge arrangement.

In an embodiment the first semiconductor die is one of a MOSFET, an IGBT, a JFET, a SFET, a bipolar transistor, or a GaN HEMT; and wherein the second semiconductor die is a diode.

In an embodiment the lead post comprises a first portion to which the external connectors of the second set of external connectors are attached, and a second portion extending between the second set of external connectors and the first set of external connectors, to which the internal electrical connector from the second semiconductor die is attached. Thereby, the lead post is subdivided into two portions, wherein each portion is for attaching the internal electrical connectors from the respective semiconductor die.

In an embodiment the external connectors of the second set of external connectors are attached to the lead post by trapezoidal interconnect portions having a mold lock. By virtue of the trapezoidal shape of the interconnect portions and impairment of the effective via size, that is the effective conductive cross-section at the interconnect portion is mitigated. In turn, the circular-shaped mold locks may be necessary to mitigate delamination effects between the external connectors and the mold compound at the circumferential surface of the mold compound.

In an embodiment the second portion of the lead post is staggered to maintain the largest possible wire size towards the interconnect portions. By staggering the second portion of the lead post, the effective conductive cross-section seen by an incoming current is enlarged. Thereby a larger heat dissipation surface having a heat spreading effect may be facilitated.

Moreover, the semiconductor device may comprise an Over-current-protection circuit (OCP-IC) and/or a gate driver circuit. Both the OCP-IC and the gate driver may be attached to the leadframe together with the first and second semiconductor dies. Further external electrical connectors for controlling the respective ICs may be in place.

In an embodiment the first semiconductor die comprises: a control electrode, a third set of external connectors, wherein the third set of external connectors comprises at least one control connector connected to the control electrode of the first semiconductor die, and wherein the third set of external connectors is laterally separated from the first set of external connectors by the second set of external connectors.

According to a second aspect of the disclosure a Single-In-Line Package (SIP) is provided, wherein a set of external drain connectors and a set of external source connectors and a set of external control connectors are arranged along a respective circumferential package surface such that the external connectors form an asymmetrical arrangement, wherein an overall wire size of the set of external source connectors is greater than an overall wire size of the set of external drain connectors. The external connectors may form an asymmetrical arrangement in the following senses: and symmetrical lead count, an asymmetrical lead layout along one edge of the single in-line package, and/or an asymmetrical wire size along the load current path particularly regarding the external source and drain connectors.

According to a third aspect of the disclosure a system is provided, comprising a first and a second semiconductor device according to the first or second aspect of the disclosure, wherein the first and the second semiconductor
device are electrically connected in parallel and arranged such that exposed outermost surfaces of each of the die carriers of the semiconductor devices are arranged in the same plane.

In an embodiment of the third aspect of the disclosure, the system further comprises a common heatsink to which the exposed outermost surfaces of each of the die carriers of the first and second semiconductor devices are thermally coupled.

### BRIEF DESCRIPTION OF THE DRAWINGS

Exemplary embodiments of the disclosure are described with reference to the following figures:

FIGS. 1a and 1b show a semiconductor device according to the disclosure.

FIGS. 2a and 2b show an inside view of a semiconductor device according to the disclosure.

FIGS. 3a and 3b show cross-sectional views of semiconductor devices according to the disclosure.

FIG. 4 shows a schematic view of a connection scheme of external connectors of a semiconductor device according to the present disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. As well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line as described herein may be a single electrically conductive element or include at least two individual electrically conductive elements connected in series and/or parallel. Electrical lines may include metal and/or semiconductor material, and may be permanently electrically conductive (i.e., non-switchable). An electrical line may have an electrical resistivity that is independent from the direction of a current flowing through it. A semiconductor body as described herein may be made of (doped) semiconductor material and may be a semiconductor chip or be included in a semiconductor chip. A semiconductor body has electrically connected pads and includes at least one semiconductor element with electrodes. The pads are electrically connected to the electrodes which includes that the pads are the electrodes and vice versa.

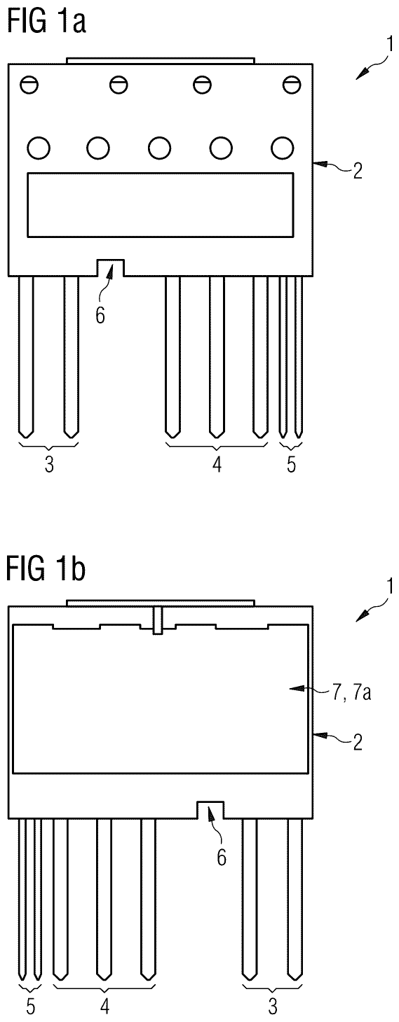

Referring to FIG. 1a, a semiconductor device 1 is shown. The semiconductor device 1 comprises a mold body 2, formed by an encapsulant. The semiconductor device 1 is a single in-line package, that is, all external connectors protrude out of the mold body at a common surface of the semiconductor device 1 which is a circumferential surface.

The semiconductor device 1 comprises a first set of external connectors 3. The first set of external connectors 3 are the drain connectors of the semiconductor device 1. Further, the semiconductor device 1 comprises a second set of external connectors 4. The second set of external connectors 4 are the source connectors of the semiconductor device 1. Still further, the semiconductor device 1 comprises a third set of external connectors 5.

The external connectors are embodied as leads or pins protruding out of the mold body 2 and being configured to couple circuitry from an inside of the mold body to further external devices (not shown).

The second set of external connectors 4 is laterally spaced apart from the first set of external connectors 3 to maintain a required clearance distance between the different voltage domains of the external connectors. Particularly, the clearance distance is larger than both a distance between leads of the first set of external connectors 3 and leads of the second set of external connectors 4.

To enlarge a creepage distance along the surface of the mold body 2 between the first set of external connectors 3 and the second set of external connectors 4, a recess/pocket 6 is arranged in the circumferential surface between the first set of external connectors 3 and the second set of external connectors 4.

The second set of external connectors 4 comprises three leads, whereas the first set of external connectors 3 comprises only two leads. Thus, the drain connectors and the source connectors have an asymmetric pin count. As a result, an ampacity of the second set of external connectors 4 is larger than an ampacity of the first set of external connectors 3. As a further result, the ampacity is not constant along the load current path.

Both the leads of the first set of external connectors 3 and the leads of the second set of external connectors 4 have the same pitch, that is, the same spacing between one another.

The third set of external connectors 5 is arranged adjacent to the second set of external connectors 4. The third set of external connectors 5 are control connectors to connect to control circuitry inside the mold body 2. For example, the control connectors 5 may connect to a gate driver circuit or to a gate electrode of a semiconductor die inside the mold body 2.

Cross sections of the leads of the first set of fixed external connectors 3 equal cross sections of the leads of the second set external connectors 4.

FIG. 1b shows the semiconductor device 1 of FIG. 1a from a back-side view. The pin layout is the same as in FIG. 1a. At the backside, an exposed portion of a die carrier 7, that is an exposed a die pad 7a is visible. The exposed die pad 7a forms a planar surface with an outermost portion of the mold body 2. Thereby, the semiconductor device 1 is configured to be attached to a planar heatsink by adjoining the exposed die pad 7a to a corresponding surface of the heatsink.

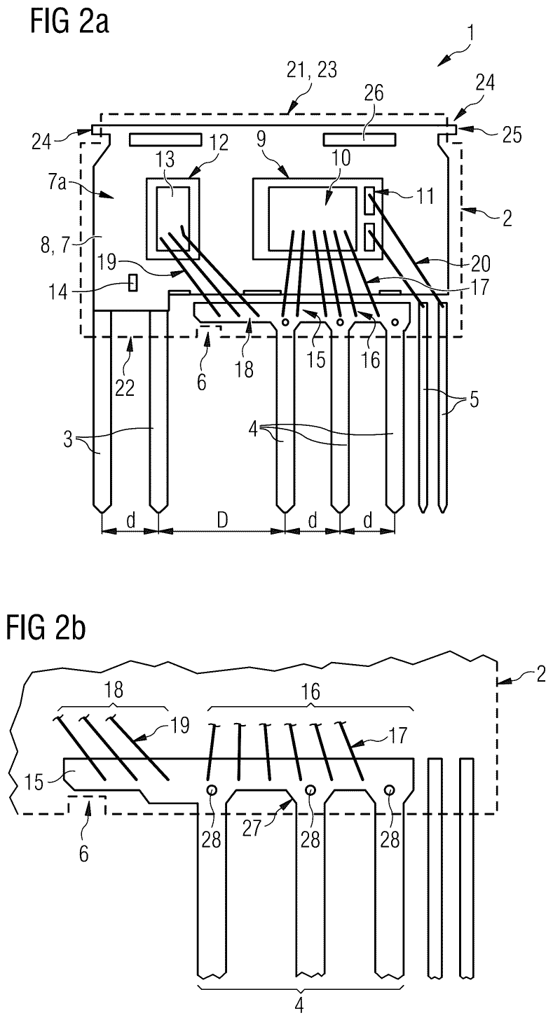

FIG. 2a shows an inside view of a semiconductor device 1 according to embodiments of the disclosure.

The semiconductor device 1 comprises an encapsulant forming the mold body 2. Inside the encapsulant a lead frame 8 comprising a first portion forming the die pad 7a is provided. A first semiconductor die 9 is attached to the leadframe 8. The first semiconductor die 9 comprises a first load electrode 9a (not visible) which is the drain electrode. The first semiconductor die 9 is attached to the die pad 7a by way of a die attach adhesive, for example soft soldering. The first semiconductor die 9 further comprises a second load electrode 10, which is a source electrode. Further, the first semiconductor die 9 comprises at least one control electrode 11, which may be a gate or temperature sense electrode.

The semiconductor device 1 further comprises a second semiconductor die 12. The second semiconductor die 12 is a diode, also having a first and a second load electrode 13, wherein the first load electrode is coupled to the die pad 7a and wherein the second load electrode 13 is arranged on an uppermost surface of the second semiconductor die 12 opposite the first load electrode (not visible).

The first set of external connectors 3, that is the external drain connectors, form an integral part with the die pad 7a. The first set of external connectors 3 is electrically connected both to the first load electrode 9a of the first semiconductor die 9 and to the first load electrode of the second semiconductor die 12.

A first mold lock 14 is arranged at a connection portion of the first set of external connectors 3. Further the semiconductor device 1 comprises a lead post 15. The lead post 15 forms one integral part with the second set of external connectors 4. The lead post 15 is described in more detail below in connection with FIG. 2b.

The second load electrode 10 of the first semiconductor die 9 is electrically connected to a first portion 16 of the lead post 15 by a first set of internal electrical connectors 17, for example bonding wires.

The second load electrode 13 of the second semiconductor die 12 is electrically coupled to a second portion 18 of the lead post 15 by a second set of internal electrical connectors 19, for example bonding wires.

The at least one control electrode 11 is electrically connected, by a third set of internal electrical connectors 20, to the third set of external connectors 5.

The mold body 2 comprises a circumferential surface 21. All of the electrical connectors protrude out of a first portion 22 of the circumferential first surface 21 forming a single in-line package (SIP). Opposite the first portion 22 of the circumferential surface 21 a second portion 23 of the circumferential surface 21 is provided. The second portion 23 of the circumferential surface 21 comprises step-shaped recesses 24. The recesses 24 are provided at outer corners of the mold body 2. A second portion of the lead frame, which is forming a tie-bar 25 protrudes out of a surface portion of each recess 24. The tie-bar 25 is an integral part of ground metal of the leadframe 8.

At an outermost portion of the second portion of the leadframe 8, second mold locks 26 are provided.

The first set of external connectors 3 comprises two leads. The leads of the first set of external connectors are spaced apart from one another by a first distance d. The first distance d may also be referred to as the pitch of the leads.

The second set of external connectors 4 comprises three leads. Hence, the second set of external connectors 4 comprises more leads than the first set of external connectors 3. The leads of the second set of external connectors 4 are also spaced apart from one another by the first distance d. However, the first set of external connectors 3 is spaced apart from the second set of external connectors 4 by a larger distance D. The larger distance D is a clearance distance between the external source connection and the external drain connection of the semiconductor device 1. The clearance distance D is larger than the first distance d. To enlarge a creepage distance between the external source connectors and the external drain connectors the pocket 6 is provided in the circumferential surface 21 of the mold body 2.

The leads of the first set of external connectors 3 and the leads of the second set of external connectors 4 have the same cross-section, that is, the same width and thickness and are of the same material. Hence, each lead of the first set of external connectors 3 and of the second set of external connectors 4 has the same wire size, that is the same conductive cross-section.

As the second set of external connectors 4 comprises at least one more lead than the first set of external connectors, an overall effective wire size of the second set of external connectors 4 is larger than an overall effective wire size of the first set of external connectors 3. The external source connectors have a larger wire size than the external drain current connectors.

FIG. 2b shows an extended view of the lead post 15 of FIG. 2a.

The first portion 16 of the lead post 15 is one integral part with the second set of electrical connectors 4. At the first portion 16 of the lead post 15 the first set of internal electrical connectors 17, that is the first bonding wires, is electrically attached to the lead post 15. Each lead of the second set of external connectors 4 is integrally attached to the first portion of the lead post 16 by an interconnect portion 27. The interconnect portion 27 is of trapezoidal shape. That is, coming from each of the leads, a cross-section of the leads widens up towards the first portion 16 of the lead post 15. The interconnect portion 27 comprises third mold locks 28. By the shape of the interconnect portion 27 an electrically effective, that is conductive, cross-section of the leads is kept constant throughout the interconnect portion 27, despite the third mold locks 28.

The second portion 18 of the lead post 15 extends away from the second set of external connectors 4. The second portion 18 of the lead post 15 comprises a step shaped portion extending away from the second set of external connectors 4. At the second portion 18 of the lead post 15 the second set of internal electrical connectors 19 is electrically coupled to the lead post 15.

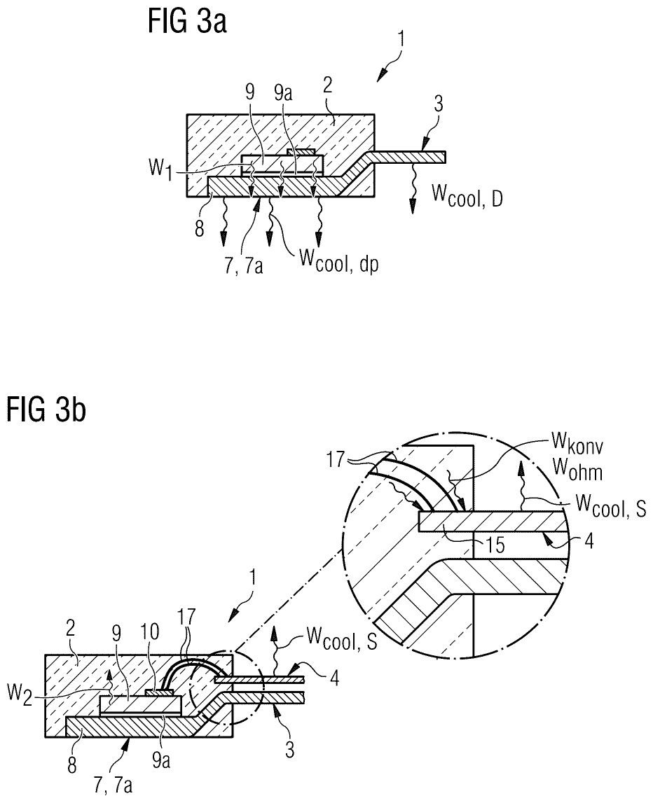

FIGS. 3a and 3b show cross-sectional views of semiconductor devices 1 according to the disclosure.

In FIG. 3a, a first amount of thermal energy W₁ is produced along the drain side of the load current path, that is a current path between the external drain connectors 3 and the first semiconductor die 9. The first semiconductor die 9 is coupled to the die carrier 7 with its first load electrode 9a. Thereby, the first semiconductor die 9, the die carrier 7 and the external drain connectors 3 heat up. However, the thermal energy W₁ is dissipated to the ambience via the die pad 7a which is exposed on the backside of the semiconductor device 1. That is, a first portion W_{cool,dp} of the thermal energy W₁ is lead away from the semiconductor device 1 by the die pad 7a, wherein the second portion W_{cool,D} is lead away from the semiconductor device 1 via the external drain connectors 3. As a result, the external drain connectors 3 have a relatively low temperature, because the first portion W_{cool,dp} of the thermal energy W₁ produced on the drain side of the load current path, has already been dissipated by the exposed die pad 7a. As the external drain connectors 3 form an integral part of the lead frame 8 and hence have a good thermal connection to the die pad 7a, the external drain connectors 3 are cooled via the die pad 7a.

In FIG. 3b, a second amount of thermal energy W₂ is produced along the source side of the load current path, that is a current path between the external source connectors 3 and the first semiconductor die 9. The load current is constant along of the load current path, that is, constant along a path from the external drain connectors 3 via the semiconductor die 9 to the external source connectors 4.

As the semiconductor die and almost all of the source side of the load current path is encapsulated by the mold compound, the thermal energy W₂ cannot be effectively led to an outside of the semiconductor device 1. That is, less cooling occurs at the source side of the load current path than at the drain side of the load current path although the amount of thermal energy produced is approximately the same (W₁=W₂).

As a result, there is only one portion of the source side load current path, where the thermal energy can be lead away from the semiconductor device 1, that is dissipated to the ambience. That portion is the second set of external connectors 4, the external source connectors. A transfer of thermal energy W_{cool,s} is enabled by the source leads 3. As the lead post 15, with which the leads of the second set of external connectors 4 are connected, is electrically and thermally connected to the first set of internal electrical connectors 17, the respective portion 16 of the lead post 15 will even receive more thermal energy. Firstly, it receives the thermal energy which is produced by its own ohmic resistance. Secondly, it receives an additional amount of thermal energy by thermal convection from the first set of internal electrical connectors 17. Consequently, the second set of external connectors 4 heats up by ohmic resistance and convection, at least at its proximal ends being buried inside the mold compound, well isolated from the ambience. This results in increased temperatures at the source connectors, compared to the drain connectors.

It is to be noted that in FIG. 3b the first set of external connectors 3 and the second set of external connectors 4 are shown as being vertically stacked. However, this is only for better oversight. The connectors are—in a Single-In-Line-Package (SIP)—all in a row adjacent to one another.

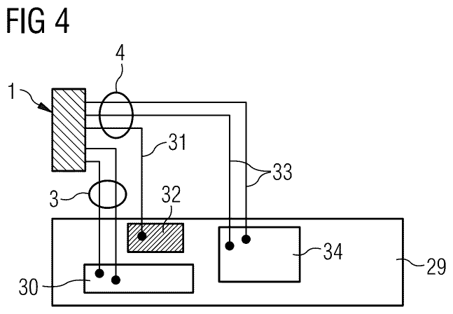

FIG. 4 shows a schematic view of a second level connection scheme of the semiconductor device 1. The semiconductor device 1, which can be a THD or a SMD, is mounted onto a printed circuit board (PCB) 29. The first set of external connectors 3 is connected to a first portion 30 of the PCB 29, which may be a drain portion. The second set of external connectors 4 comprises three leads, wherein a first lead 31 is connected to a second portion 32 of the PCB, and second leads 33 are connected to a third portion 34 of the PCB.

The second portion 32 of the PCB is an isolated portion which acts as a heat sink. The second portion of the PCB 32 may be an isolated copper plated area on the PCB 29. To connect to the second portion of the PCB 32, the first lead 31 may be shaped differently than the second leads 33. For example, the first lead 31 may comprise steps, downsets, a J-shape, a gullwing shape or may be bent in any suitable form.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

### LIST OF REFERENCE SIGNS

1 semiconductor device
2 mold body
3 first set of external connectors
4 second set of external connectors
5 third set of external connectors
6 pocket/recess
7 die carrier
7a die pad
8 leadframe
9 first semiconductor die
9a first load electrode
10 second load electrode / source electrode
11 control electrode
12 second semiconductor die
13 second load electrode of the second semiconductor die
14 first mold lock
15 lead post
16 first portion of the lead post
17 first internal electrical connectors
18 second portion of the lead post
19 second internal electrical connectors
20 third internal electrical connectors
21 circumferential surface of the mold body
22 first portion of the circumferential surface
23 second portion of the circumferential surface
24 step-shaped recesses
25 tie-bar
26 second mold lock
27 interconnect portion
28 third mold locks
29 PCB
30 First portion of the PCB
31 First lead /thermal pin of the second set of external connectors
32 Second portion of the PCB
33 Second leads of the second set of external connectors
34 Third portion of the PCB

What is claimed is:

1. A semiconductor device, comprising:
a die carrier;
a first semiconductor die comprising at least a first load electrode and a second load electrode, wherein the first semiconductor die is mounted onto the die carrier with the first load electrode being electrically connected to the die carrier;
a first set of external connectors electrically and thermally connected to the die carrier; and
a second set of external connectors spaced apart from the die carrier and electrically connected to the second load electrode,
wherein an overall wire size of the second set of external connectors is greater than an overall wire size of the first set of external connectors.

2. The semiconductor device of claim 1, further comprising:
an encapsulant encapsulating at least part of the first semiconductor die and at least proximal ends of each of the external connectors such that distal ends of both the external connectors of the first set of external connectors and the second set of external connectors protrude out of the encapsulant.

3. The semiconductor device of claim 2, wherein an outermost surface of the die carrier is exposed from the encapsulant.

4. The semiconductor device of claim 3, wherein the outermost surface of the die carrier is configured to be attached to a heatsink.

5. The semiconductor device of claim 2, wherein the second set of external connectors is spaced apart from the first set of external connectors, and wherein a pocket is arranged in a circumferential surface of the encapsulant between the first and second sets of external connectors.

6. The semiconductor device of claim 1, wherein the die carrier is a leadframe, and wherein the leadframe comprises a first portion forming a die pad.

7. The semiconductor device of claim 6, wherein the first set of external connectors is an integral part with the first portion of the leadframe.

8. The semiconductor device of claim 1, wherein the second set of external connectors comprises at least one additional connector with respect to the first set of external connectors.

9. The semiconductor device of claim 8, wherein the at least one additional connector is a thermal connector configured to facilitate heat transfer from an inside of the semiconductor device to the ambient environment.

10. The semiconductor device of claim 8, wherein the at least one additional connector is configured to be attached to a heatsink.

11. The semiconductor device of claim 1, further comprising:
a lead post attached to the second set of external connectors, the lead post forming an integral part with the second set of external connectors.

12. The semiconductor device of claim 11, further comprising:
a second semiconductor die attached to the die carrier,
wherein the second semiconductor die is electrically and thermally connected to the lead post by an internal electrical connector.

13. The semiconductor device of claim 12, wherein the lead post comprises a first portion to which the external connectors of the second set of external connectors are attached, and a second portion extending between the second set of external connectors and the first set of external connectors, to which the internal electrical connector from the second semiconductor die is attached.

14. The semiconductor device of claim 13, wherein the external connectors of the second set of external connectors are attached to the lead post by trapezoidal interconnect portions having a mold lock.

15. The semiconductor device of claim 14, wherein the second portion of the lead post is staggered to maintain a largest possible wire size towards the trapezoidal interconnect portions.

16. The semiconductor device of claim 12, wherein the first semiconductor die is one of a MOSFET, an IGBT, a JFET, a SFET, a bipolar transistor, or a GaN HEMT, and wherein the second semiconductor die is a diode.

17. The semiconductor device of claim 1, wherein the semiconductor device is a single-in-line-package, and wherein the first set of external connectors is laterally spaced apart from the second set of external connectors by a distance larger than both a distance between external connectors of the first set of external connectors and a distance between external connectors of the second set of external connectors.

18. The semiconductor device of claim 1, wherein the first set of external connectors has a downset towards the die carrier.

19. The semiconductor device of claim 1, wherein a cross-section of each connector of the first set of external connectors equals a cross-section of each connector of the second set of external connectors.

20. The semiconductor device of claim 1, wherein the die carrier comprises a second portion forming a tie-bar, and wherein the second portion is arranged at an opposite side with respect to the external connectors.

21. The semiconductor device of claim 1, further comprising:
an over-current-protection circuit and/or a gate driver circuit.

22. The semiconductor device of claim 1, wherein the first semiconductor die further comprises: a control electrode and a third set of external connectors, wherein the third set of external connectors comprises at least one control connector connected to the control electrode, and wherein the third set of external connectors is laterally separated from the first set of external connectors by the second set of external connectors.

23. A single-in-line package, comprising:
a set of external drain connectors, a set of external source connectors and a set of external control connectors arranged along a respective circumferential package surface such that the external connectors form an asymmetrical arrangement, wherein an overall wire size of the set of external source connectors is greater than an overall wire size of the set of external drain connectors.

24. A system comprising a first and a second semiconductor device according to claim 1, wherein the first and the second semiconductor device are electrically connected in parallel and arranged such that exposed outermost surfaces of each of the die carriers of the semiconductor devices are arranged in a same plane.

25. The system of claim 24, further comprising a common heatsink to which an exposed outermost surface of each of the die carriers of the first and second semiconductor devices are thermally coupled.
